(19) United States
(12) Patent Application Publication
(10) Pub. No.: US 2015/0309083 A1
(43) Pub. Date: Oct. 29, 2015

(54) A SENSOR COMPRISING A SUBSTRATE

(71) Applicant: Danfoss A/S, Nordborg (DK)

(72) Inventor: Steen Moellebjerg Matzen, Sydals (DK)

(21) Appl. No.: 14/649,769

(22) PCT Filed: Nov. 28, 2013
(86) PCT No.: PCT/DK2013/050400

§ 371 Date: Jun. 4, 2015

(30) Foreign Application Priority Data
Dec. 17, 2012 (DK) PA 2012 00800

(51) Int. Cl. G01R 17/10; G01L 1/18

(52) U.S. Cl. CPC G01R 17/10; G01L 1/18

(57) ABSTRACT

A sensor (1) comprising an n-dosed/p-dosed substrate (2), and a Wheatstone bridge (3) arranged on the substrate (2) is disclosed. A field shield (4) is arranged on the substrate (2) in such a manner that the field shield (4) covers the Wheatstone bridge (3). A quasi-DC voltage is supplied to the Wheatstone bridge (3), and a DC voltage is supplied to the substrate (2), the level of said DC voltage being higher/lower than or equal to the quasi-DC voltage supplied to the Wheatstone bridge (3). A voltage may be supplied to the field shield (4), the level of said voltage being higher/lower than or equal to the quasi-DC voltage supplied to the Wheatstone bridge (3).

### CROSS-REFERENCE TO RELATED APPLICATION

This application is entitled to the benefit of and incorporates by reference subject matter disclosed in International Patent Application No. PCT/DK2013/050400 filed on Nov. 28, 2013 and Danish Patent Application PA 2012 00800 filed Dec. 17, 2012.

### FIELD OF THE INVENTION

The present invention relates to a sensor, such as a pressure sensor, comprising a substrate having measuring electronics including a Wheatstone bridge arranged thereon.

### BACKGROUND

Sensors, such as pressure transmitters, based on piezo resistive MEMS sensor chips are known. For instance, U.S. Pat. No. 6,933,582 discloses a semiconductor sensor including a p-type semiconductor substrate having an n-type semiconductor layer disposed on one surface of the substrate and a p-type diffused resistor disposed in the n-type semiconductor layer. A first electric voltage is applied to the n-type semiconductor layer, a second electric voltage is applied to the substrate, a third electric voltage is applied to the p-type diffused resistor. The first electric voltage is higher than the second and third electric voltages. The sensor ensures stable operation against electric leakage and high noise protection because two depletion layers are formed.

U.S. Pat. No. 5,681,997 discloses a polycrystalline pressure sensor formed by depositing polycrystalline silicon piezo resistors on a polycrystalline sensing diaphragm. The piezo resistors are arranged in a Wheatstone bridge configuration. During operation, an alternating differential signal is applied across the input of the Wheatstone bridge. A measured voltage difference between the output terminals of the Wheatstone bridge is used to detect imbalance in the electrical piezo resistors that corresponds to pressure applied to the sensor.

### SUMMARY

It is an object of embodiments of the invention to provide a sensor which operates in a more reliable manner than prior art sensors.

It is a further object of embodiments of the invention to provide a sensor in which electromagnetic interference (EMI) effects are reduced as compared to prior art sensors.

It is an even further object of embodiments of the invention to provide a sensor which has an increased stability, as compared to prior art sensors, at high temperature over time.

According to a first aspect the invention provides a sensor comprising:
an n-dosed substrate,
measuring electronics arranged at least partly on the substrate, said measuring electronics comprising a Wheatstone bridge,
a field shield arranged on the substrate in such a manner that the field shield covers the Wheatstone bridge,
a power supply arranged to supply electrical voltage to the substrate and the measuring electronics, in such a manner that:
   a quasi-DC voltage is supplied to the Wheatstone bridge, and
   a DC voltage is supplied to the substrate, the level of said DC voltage being higher than or equal to the quasi-DC voltage supplied to the Wheatstone bridge.

According to a second aspect the invention provides a sensor comprising:
a p-dosed substrate,
measuring electronics arranged at least partly on the substrate, said measuring electronics comprising a Wheatstone bridge,
a field shield arranged on the substrate in such a manner that the field shield covers the Wheatstone bridge,
a power supply arranged to supply electrical voltage to the substrate and the measuring electronics, in such a manner that:
   a quasi-DC voltage is supplied to the Wheatstone bridge, and
   a DC voltage is supplied to the substrate, the level of said DC voltage being lower than or equal to the quasi-DC voltage supplied to the Wheatstone bridge.

The sensor comprises a substrate. According to the first aspect of the invention, the substrate is an n-dosed substrate, and according to the second aspect of the invention, the substrate is a p-dosed substrate. The substrate may, e.g., be made from a semiconductor material, such as silicon, germanium, gallium arsenide, silicon carbide, etc.

The sensor further comprises measuring electronics arranged at least partly on the substrate. Thus, all of the measuring electronics may be arranged on the substrate. Alternatively, some parts or components of the measuring electronics may be arranged on the substrate, while other parts or components of the measuring electronics may be arranged in other parts of the sensor, and/or arranged outside the sensor and simply connected to the parts or components of the measuring electronics which are arranged on the substrate.

The measuring electronics comprises a Wheatstone bridge. The Wheatstone bridge is preferably arranged on the substrate. The Wheatstone bridge provides the actual measuring performed by the sensor. This will be described in further detail below.

The sensor further comprises a field shield arranged on the substrate in such a manner that the field shield covers the Wheatstone bridge. The field shield thereby provides shielding for the Wheatstone bridge against external electromagnetic fields which could potentially disturb the measurements performed by means of the Wheatstone bridge. The field shield is preferably made from a metal, such as aluminum.

Finally, the sensor comprises a power supply arranged to supply electrical voltage to the substrate and the measuring electronics, in particular to the Wheatstone bridge.

The power supply supplies a quasi-DC voltage to the Wheatstone bridge. In the present context the term ‘quasi-DC voltage’ should be interpreted to mean a voltage signal which is alternatingly switched between an upper voltage level and a lower voltage level, in such a manner that the upper voltage level is supplied to one node of the Wheatstone bridge when the lower voltage level is supplied to another node of the Wheatstone bridge, and vice versa. At specified time intervals, the voltage levels are reversed, so that the voltage level supplied to one node is switched from the upper level to the lower level, while the voltage level supplied to the another node is switched from the lower level to the upper level, etc.

Furthermore, the power supply supplies a DC voltage to the substrate. In the case that the sensor is a sensor according to the first aspect of the invention, i.e. in the case that the substrate is an n-dosed substrate, the level of the DC voltage supplied to the substrate is higher than or equal to the quasi-DC voltage supplied to the Wheatstone bridge. Similarly, in the case that the sensor is a sensor according to the second aspect of the invention, i.e. in the case that the substrate is a p-dosed substrate, the level of the DC voltage supplied to the substrate is lower than or equal to the quasi-DC voltage supplied to the Wheatstone bridge. Thereby it is ensured that a voltage difference between the voltage supplied to the substrate and to the Wheatstone bridge is present, at least for a part of the period defined by the quasi-DC voltage. This has the consequence that the electron leakage, as well as electrical capacitance between the four nodes of the Wheatstone bridge and a casing or chassis of the sensor is reduced, as compared to a situation where the voltage supplied to the Wheatstone bridge is equal to the voltage supplied to the substrate at any time. The thickness of the depletion layer increases with voltage, thus minimizing the capacitance. Minimizing the capacitive coupling between the sensing element and the outer casing or chassis of the sensor will minimize the electromagnetic interference (EMI) effects of the sensor, thereby improving EMC common mode performance. Furthermore, the sensor operates in a very reliable manner. This is because the temperature stability of the sensor is improved by minimising diffusion caused by DC voltage of free ions, thus minimising changes in piezo resistive properties.

The power supply may further be arranged to supply a voltage to the field shield. In the case that the sensor is a sensor according to the first aspect of the invention, i.e. in the case that the substrate is an n-dosed substrate, the level of the voltage supplied to the field shield is higher than or equal to the quasi-DC voltage supplied to the Wheatstone bridge. Similarly, in the case that the sensor is a sensor according to the second aspect of the invention, i.e. in the case that the substrate is a p-dosed substrate, the level of the voltage supplied to the field shield is lower than or equal to the quasi-DC voltage supplied to the Wheatstone bridge. Thus, according to this embodiment, a voltage difference exists between the voltage supplied to the field shield, and either the voltage supplied to the Wheatstone bridge or the voltage supplied to the substrate. Thereby the sensor is efficiently shielded against external electrical fields, and the sensor operates in a very reliable manner.

The level of the DC voltage supplied to the substrate may be equal to the level of the voltage supplied to the field shield. This may, e.g., be obtained by providing a direct electrical connection between the field shield and the substrate. According to this embodiment, the voltage supplied to the field shield is a DC voltage.

As an alternative, the voltage supplied to the field shield may follow the quasi-DC voltage supplied to the Wheatstone bridge. This may, e.g., be obtained by providing a direct electrical connection between the field shield and the Wheatstone bridge. According to this embodiment, the voltage supplied to the field shield is a quasi-DC voltage.

The difference between the DC voltage level supplied to the substrate and the quasi-DC voltage supplied to the Wheatstone bridge may be at least 0.5 V, such as at least 1.0 V, such as at least 3.0 V, such as at least 5.0 V, such as at least 7.0 V, such as at least 10.0 V. This is an advantage, because a large difference between the voltage levels minimises the capacitance between the four nodes of the Wheatstone bridge and a casing or chassis of the sensor. However, electron leakage and diffusion, which would be a problem at large voltage differences in the case that a DC voltage was supplied to the Wheatstone bridge as well as to the substrate, is minimised due to the quasi-DC voltage supplied to the Wheatstone bridge.

The measuring electronics may further comprise one or more resistors, each resistor being electrically connected between the power supply and an excitation node of the Wheatstone bridge. The voltage drop provided by the resistors, bias the diodes of the Wheatstone bridge in the reverse direction. In the case that the sensor is a sensor according to the first aspect of the invention, i.e. in the case that the substrate is an n-dosed substrate, this reduces the voltage level supplied by the power supply, and the quasi-DC voltage level supplied to the Wheatstone bridge is thereby reduced as compared to the original DC voltage level provided by the power supply, and which is also supplied to the substrate. Similarly, in the case that the sensor is a sensor according to the second aspect of the invention, i.e. in the case that the substrate is a p-dosed substrate, this increases the voltage level supplied by the power supply, and the quasi-DC voltage level supplied to the Wheatstone bridge is thereby increased as compared to the original DC voltage level provided by the power supply, and which is also supplied to the substrate. Thus, according to this embodiment, a difference in voltage level between the substrate and the Wheatstone bridge is present throughout the period defined by the quasi-DC voltage supplied to the Wheatstone bridge.

In the case that the sensor is a sensor according to the first aspect of the invention, i.e. in the case that the substrate is an n-dosed substrate, the Wheatstone bridge may be formed by p-dosed resistors implemented in the substrate. Similarly, in the case that the sensor is a sensor according to the second aspect of the invention, i.e. in the case that the substrate is a p-dosed substrate, the Wheatstone bridge may be formed by n-dosed resistors implemented in the substrate. According to this embodiment, the Wheatstone bridge is formed directly into the substrate.

The sensor may be a piezo-resistive MEMS sensor chip.

The measuring electronics may further comprise a switching arrangement, said switching arrangement being arranged to generate a quasi-DC voltage signal and to supply the generated quasi-DC voltage signal to the Wheatstone bridge. According to this embodiment, the power supply is a DC power supply, and the switching arrangement ensures that the voltage supplied to the Wheatstone bridge is a quasi-DC voltage.

The sensor may be a pressure sensor. As an alternative, the sensor may be a temperature sensor, a strain gauge, a stress gauge, or any other suitable kind of sensor.

### BRIEF DESCRIPTION OF THE DRAWINGS

The invention will now be described in further detail with reference to the accompanying drawings in which

FIG. 1 is a diagrammatic view of a sensor according to a first embodiment of the invention,

FIG. 2 is a diagrammatic view of a sensor according to a second embodiment of the invention,

FIG. 3 illustrates voltages supplied to the sensor of FIG. 1, and

FIG. 4 is a cross sectional view of a sensor according to an embodiment of the invention.

### DETAILED DESCRIPTION

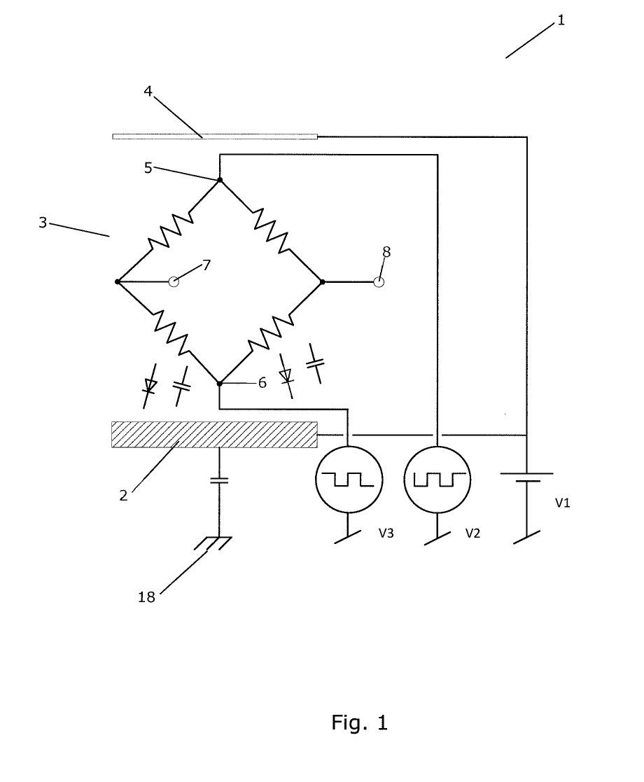

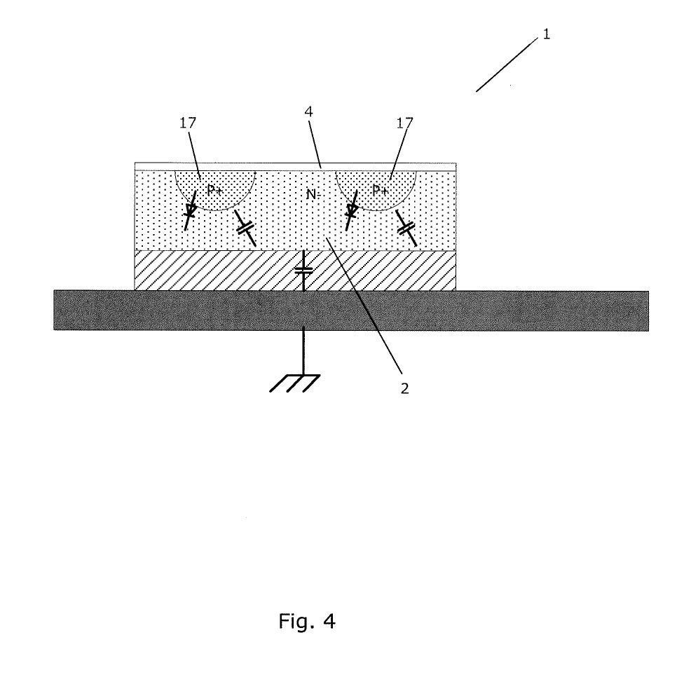

FIG. 1 is a diagrammatic view of a sensor 1 according to a first embodiment of the invention. The sensor 1 comprises an n-dosed substrate 2. It should be noted that, even though the substrate 2 illustrated in FIG. 1 is an n-dosed substrate, it is within the scope of the present invention that the substrate 2 could be a p-dosed substrate. In this case the anode cathode of the illustrated diodes should be reversed. A Wheatstone bridge 3 is arranged on the substrate 2, e.g. formed directly in the substrate 2 in a manner which will be described below with reference to FIG. 4.

A field shield 4 is arranged on the substrate 2 in such a manner that it covers the Wheatstone bridge 3. Thereby the field shield 4 shields the Wheatstone bridge 3 against external electrical fields.

A power supply is arranged to supply a first voltage level, V₁, in the form of a DC voltage to the substrate 2 and to the field shield 4. Furthermore, the power supply supplies a second voltage level, V₂, in the form of a first quasi-DC voltage to a first node 5 of the Wheatstone bridge 3, and a third voltage level, V₃, in the form of a second quasi-DC voltage to a second node 6 of the Wheatstone bridge 3. Accordingly, the voltages, V₂ and V₃, both alternate between an upper level and a lower level in such a manner that the voltage is initially maintained substantially constant at the upper level, then switched abruptly to the lower level and maintained substantially constant at the lower level before being switched abruptly back to the upper level, etc. Thus, each of the quasi-DC voltages, V₂ and V₃, defines a period, e.g. being the time elapsing from the voltage is switched to the upper level until the voltage is once again switched to the upper level. Furthermore, when the upper voltage level is supplied to the first node 5, the lower voltage level is supplied to the second node 6, and vice versa.

It is an advantage that quasi-DC voltages, V₂ and V₃, are supplied to the nodes 5, 6 of the Wheatstone bridge 3, because this minimizes the diffusion of ions, which could pollute the resistors of the Wheatstone bridge 3. Thereby the performance of the sensor 1 can be improved.

In the case that the substrate 2 is an n-dosed substrate, the quasi-DC voltages, V₂ and V₃, are selected in such a manner that, at any time during a period of the quasi-DC voltages, the DC voltage, V₁, is higher than or equal to the quasi-DC voltages, V₂ and V₃. Thus, the quasi-DC voltages, V₂ and V₃, may be equal to the DC voltage, V₁, during the part of the period where the quasi-DC voltages are at the upper voltage level. However, for the remaining part of the period, i.e. when the quasi-DC voltages are at the lower voltage level, the DC voltage, V₁, which is supplied to the substrate 2 and to the field shield 4, will be higher than the quasi-DC voltages, V₂ and V₃. The DC voltage, V₁, may even be higher than the quasi-DC voltages, V₂ and V₃, during the entire period of the quasi-DC voltages.

Similarly, in the case that the substrate 2 is a p-dosed substrate, the quasi-DC voltages, V₂ and V₃, are selected in such a manner that, at any time during a period of the quasi-DC voltages, the DC voltage, V₁, is lower than or equal to the quasi-DC voltages, V₂ and V₃. Thus, similarly to what is described above, the DC voltage, V₁, is lower than the quasi-DC voltages, V₂ and V₃, for at least a part of the period defined by the quasi-DC voltages.

Accordingly, regardless of whether the substrate 2 is an n-dosed substrate or a p-dosed substrate, a voltage difference exists between the voltage level supplied to the substrate 2 and the field shield 4, on the one hand, and the first 5 and second 6 nodes of the Wheatstone bridge 3, on the other hand, at least for a part of the period defined by the quasi-DC voltages. This ensures that the capacitance between the four nodes of the Wheatstone bridge 3 and a casing or chassis 18 of the sensor 1 is minimised, and thereby that the electromagnetic interference effects are reduced.

The sensor 1 of FIG. 1 may be operated in the following manner. Measuring electronics are connected to nodes 7 and 8 of the Wheatstone bridge 3. Voltages are supplied to the substrate 2, the field shield 4 and the first 5 and second 6 nodes of the Wheatstone bridge 3 as described above. Changes in a quantity to be measured, such as pressure, strain, stress, temperature, etc., cause the resistances of the resistors of the Wheatstone bridge 3 to change. This will, in turn, cause the voltage difference between nodes 7 and 8 to change. This change in voltage difference is detected by the measuring electronics, and is used for deriving the changes in the quantity being measured. With an appropriate calibration of the sensor 1, an absolute value of the quantity being measured can be derived.

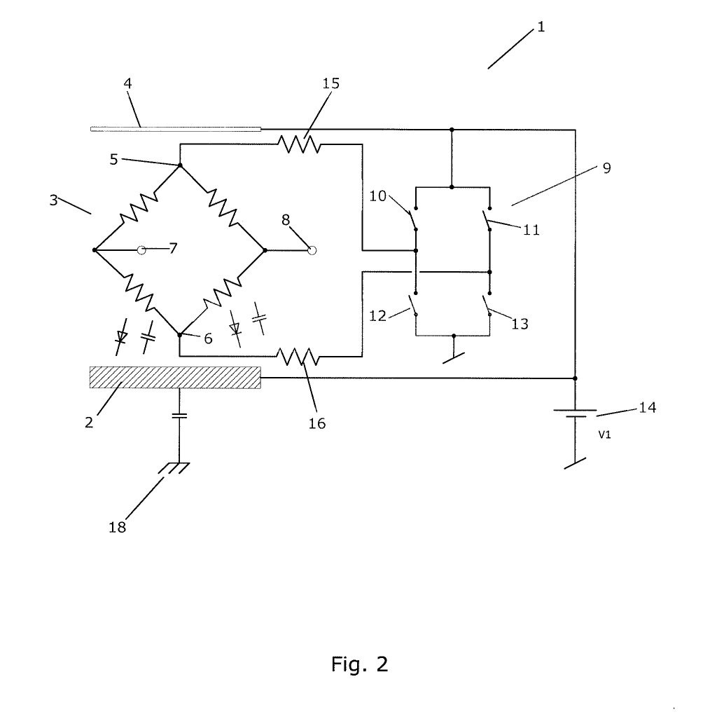

FIG. 2 is a diagrammatic view of a sensor 1 according to a second embodiment of the invention. The sensor 1 of FIG. 2 is very similar to the sensor 1 of FIG. 1, and it will therefore not be described in detail here.

The sensor 1 of FIG. 2 comprises a switching arrangement 9 comprising four switches 10, 11, 12, 13 which can be alternatingly opened and closed. In FIG. 2 all four switches 10, 11, 12, 13 are shown in the open position. The switching arrangement 9 is electrically connected between a DC power supply 14 and the Wheatstone bridge 3. The DC power supply 14 is also electrically connected to the substrate 2 and the field shield 4 in such a manner that the DC voltage level supplied by the power supply 14 is the DC voltage level which is supplied to the substrate 2 and the field shield 4.

When switch 10 and switch 13 are closed, and switch 11 and switch 12 are open, an upper voltage level is supplied to the first node 5 of the Wheatstone bridge 3, and a lower voltage level is supplied to the second node 6 of the Wheatstone bridge 3. Similarly, when switch 10 and switch 13 are open, and switch 11 and switch 12 are closed, a lower voltage level is supplied to the first node 5 of the Wheatstone bridge 3, and an upper voltage level is supplied to the second node 6 of the Wheatstone bridge 3. Thus, by switching the switches 10, 11, 12, 13 of the switching arrangement 9 in an appropriate manner, the quasi-DC voltages illustrated in FIG. 1 can be supplied to the Wheatstone bridge 3.

A first biasing resistor 15 is arranged between the switching arrangement 9 and the first node 5 of the Wheatstone bridge 3, and a second biasing resistor 16 is arranged between the switching arrangement 9 and the second node 6 of the Wheatstone bridge 3. The biasing resistors 15, 16 lower the voltage level supplied by the DC power supply 14. Thereby, even the upper voltage level of the quasi-DC voltages supplied to the first 5 and second 6 nodes of the Wheatstone bridge 3, is lower than the DC voltage level supplied to the substrate 2 and the field shield 4.

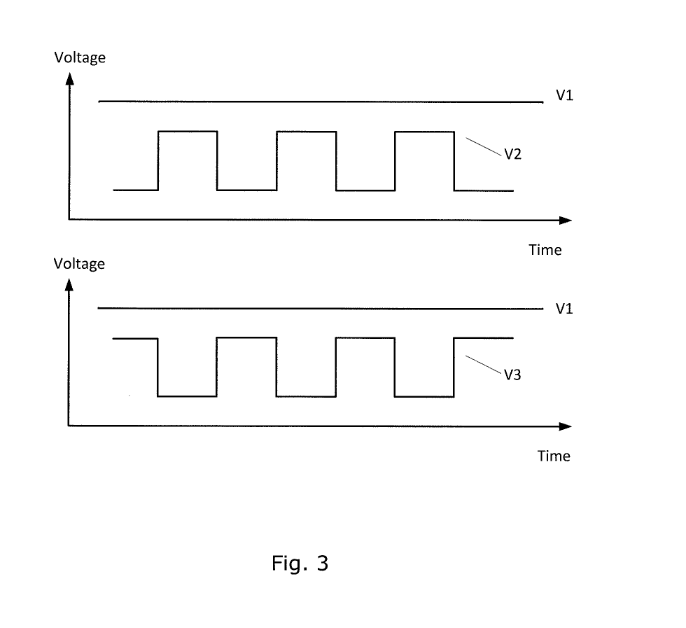

FIG. 3 illustrates the voltage levels, V₁, V₂ and V₃, supplied to the substrate 2, the field shield 4 and the Wheatstone bridge 3 of the sensor 1 of FIG. 1, as a function of time. FIG. 3 illustrates the situation where the substrate 2 is an n-dosed substrate.

It is clear from FIG. 3 that the DC voltage, V₁, supplied to the substrate 2 and to the field shield 4, is higher than the quasi-DC voltages, V₂ and V₃, supplied to the first 5 and second 6 nodes, respectively, of the Wheatstone bridge 3, at all times. It can also be seen that when the quasi-DC voltage, V₂, supplied to the first node 5 of the Wheatstone bridge 3 is at the upper level, the quasi-DC voltage, V₃, supplied to the second node 6 of the Wheatstone bridge 3 is at the lower level, and vice versa.

FIG. 4 is a cross sectional view of a sensor 1 according to an embodiment of the invention. The sensor 1 comprises an n-dosed substrate 2, into which resistors 17 of a p-dosed material are formed. The resistors 17 form a Wheatstone bridge, and the sensor 1 may therefore, e.g., be of the kind shown in FIG. 1 or of the kind shown in FIG. 2.

A field shield 4 is arranged on the substrate 2 in such a manner that it covers the resistors 17.

Voltages can be supplied to the substrate 2, the field shield 4 and the resistors 17 in the manner described above.

The embodiments of the invention described above are provided by way of example only. The skilled person will be aware of many modifications, changes and substitutions that could be made without departing from the scope of the present invention. The claims of the present invention are intended to cover all such modifications, changes and substitutions as fall within the spirit and scope of the invention.

What is claimed is:

1. A sensor comprising:
an n-dosed substrate,
measuring electronics arranged at least partly on the substrate, said measuring electronics comprising a Wheatstone bridge,
a field shield arranged on the substrate in such a manner that the field shield covers the Wheatstone bridge,
a power supply arranged to supply electrical voltage to the substrate and the measuring electronics, in such a manner that:
a quasi-DC voltage is supplied to the Wheatstone bridge, and
a DC voltage is supplied to the substrate, the level of said DC voltage being higher than or equal to the quasi-DC voltage supplied to the Wheatstone bridge.

2. The sensor according to claim 1, wherein the power supply is further arranged to supply electrical voltage to the field shield in such a manner that the level of the voltage supplied to the field shield is higher than or equal to the quasi-DC voltage supplied to the Wheatstone bridge.

3. The sensor according to claim 2, wherein the level of the DC voltage supplied to the substrate is equal to the level of the voltage supplied to the field shield.

4. The sensor according to claim 2, wherein the voltage supplied to the field shield follows the quasi-DC voltage supplied to the Wheatstone bridge.

5. The sensor according to any of the claim 1, wherein the difference between the DC voltage level supplied to the substrate and the quasi-DC voltage supplied to the Wheatstone bridge is at least 0.5 V.

6. The sensor according to claim 1, wherein the measuring electronics further comprises one or more resistors, each resistor being electrically connected between the power supply and an excitation node of the Wheatstone bridge.

7. The sensor according to claim 1, wherein the Wheatstone bridge is formed by p-dosed resistors implemented in the substrate.

8. The sensor according to claim 1, wherein the sensor is a piezo-resistive MEMS sensor chip.

9. The sensor according to claim 1, wherein the measuring electronics further comprises a switching arrangement, said switching arrangement being arranged to generate a quasi-DC voltage signal and to supply the generated quasi-DC voltage signal to the Wheatstone bridge.

10. The sensor according to claim 1, wherein the sensor is a pressure sensor.

11. A sensor comprising:
a p-dosed substrate,
measuring electronics arranged at least partly on the substrate, said measuring electronics comprising a Wheatstone bridge,
a field shield arranged on the substrate in such a manner that the field shield covers the Wheatstone bridge,
a power supply arranged to supply electrical voltage to the substrate and the measuring electronics, in such a manner that:
a quasi-DC voltage is supplied to the Wheatstone bridge, and
a DC voltage is supplied to the substrate, the level of said DC voltage being lower than or equal to the quasi-DC voltage supplied to the Wheatstone bridge.

12. The sensor according to claim 11, wherein the power supply is further arranged to supply electrical voltage to the field shield in such a manner that the level of the voltage supplied to the field shield is lower than or equal to the quasi-DC voltage supplied to the Wheatstone bridge.

13. The sensor according to claim 11, wherein the Wheatstone bridge is formed by n-dosed resistors implemented in the substrate.

14. The sensor according to claim 11, wherein the sensor is a pressure sensor.

15. The sensor according to claim 2, wherein the difference between the DC voltage level supplied to the substrate and the quasi-DC voltage supplied to the Wheatstone bridge is at least 0.5 V.

16. The sensor according to claim 3, wherein the difference between the DC voltage level supplied to the substrate and the quasi-DC voltage supplied to the Wheatstone bridge is at least 0.5 V.

17. The sensor according to claim 4, wherein the difference between the DC voltage level supplied to the substrate and the quasi-DC voltage supplied to the Wheatstone bridge is at least 0.5 V.

18. The sensor according to claim 2, wherein the measuring electronics further comprises one or more resistors, each resistor being electrically connected between the power supply and an excitation node of the Wheatstone bridge.

19. The sensor according to claim 3, wherein the measuring electronics further comprises one or more resistors, each resistor being electrically connected between the power supply and an excitation node of the Wheatstone bridge.

20. The sensor according to claim 4, wherein the measuring electronics further comprises one or more resistors, each resistor being electrically connected between the power supply and an excitation node of the Wheatstone bridge.
